(19) United States
(12) Patent Application Publication
(10) Pub. No.: US 2008/0149366 A1
(43) Pub. Date: Jun. 26, 2008

(54) INTERLEAVED PRINTED CIRCUIT BOARD

(76) Inventors: Tsuneo Suzuki, Monchweiler (DE); Rolf Dupper, VS-Villingen (DE)

Correspondence Address: BRINKS HOFER GILSON & LIONE, P.O. BOX 10395, CHICAGO, IL, 60610, US

(21) Appl. No.: 11/951,103

(22) Filed: Dec. 5, 2007

(30) Foreign Application Priority Data
Dec. 7, 2006 (EP) 06025340.8

(51) Int. Cl. H05K 1/02; H05K 3/10

(52) U.S. Cl. 174/250; 29/846

(57) ABSTRACT

A printed circuit board may move an electrical or optical component. A first trace may be supported by a substrate having a first surface. A second trace may interleave the first trace where current flow through the first trace and the second trace may generate a first magnetic field. The first and second traces may be arranged around a first point, and the first magnetic field may be operable to interact with a second magnetic field to move a movable component in a direction substantially coplanar to the first surface of the substrate.

### BACKGROUND OF THE INVENTION

1. Priority Claim

This application claims the benefit of priority from European Patent Application No. 06025340.8 filed on Dec. 7, 2006, which is incorporated by reference.

2. Technical Field

This invention relates to a printed circuit board, and more particularly, to a printed circuit board used in electrical and/or optical adjustment devices.

3. Related Art

Electrical and/or optical systems or devices may utilize movable components. An optical recording and/or reproducing devices may include an optical pickup actuator that drives or moves a lens over a storage medium, such as an optical disk. As storage capacity of storage media increases, numerical apertures of optical lenses may also increase. The increase in numerical apertures may cause errors and less accuracy with respect to operation between the optical lens and the storage medium. Systems using multi-layered arrangements of magnetic circuits may provide tilt movement or correction of an optical lens that may aid in eliminating errors. However, such systems may require relatively complicated structures to enable movement. Therefore, there is a need for a printed circuit board that is easier to manufacture and is smaller in size that can be used for more accurate operations in electrical and/or optical systems or devices.

### SUMMARY

A printed circuit board may move an electrical or optical component. A first trace may be supported by a substrate having a first surface. A second trace may interleave the first trace where current flow through the first trace and the second trace may generate a first magnetic field. The first and second traces may be arranged around a first point, and the first magnetic field may be operable to interact with a second magnetic field to move a movable component in a direction substantially coplanar to the first surface of the substrate.

Other systems, methods, features, and advantages will be, or will become, apparent to one with skill in the art upon examination of the following figures and detailed description. It is intended that all such additional systems, methods, features and advantages be included within this description, be within the scope of the invention, and be protected by the following claims.

### BRIEF DESCRIPTION OF THE DRAWINGS

The features and methods may be better understood with reference to the following drawings and description. The components in the figures are not necessarily to scale, emphasis instead being placed upon illustrating the principles of the invention. Moreover, in the figures, like referenced numerals designate corresponding parts throughout the different views.

FIG. 1 is an electrical or optical device.

FIG. 2 is a perspective view of a portion of FIG. 1.

FIG. 3 is a perspective view of a printed circuit board arranged in the device of FIG. 1 or 2.

FIG. 4 is a schematic view of a portion of a printed circuit board.

FIG. 5 is an overview of a first side of a printed circuit board.

FIG. 6 is an overview of a second side of the printed circuit board of FIG. 5.

FIG. 7 illustrates current flow on the first side of the printed circuit board of FIG. 5.

FIG. 8 illustrates current flow on the second side of the printed circuit board of FIG. 6.

FIG. 9 illustrates magnetic field areas corresponding to the first side of the printed circuit board of FIG. 5.

FIG. 10 is a flowchart illustrating a method of manufacturing a printed circuit board.

### DETAILED DESCRIPTION OF THE PREFERRED EMBODIMENTS

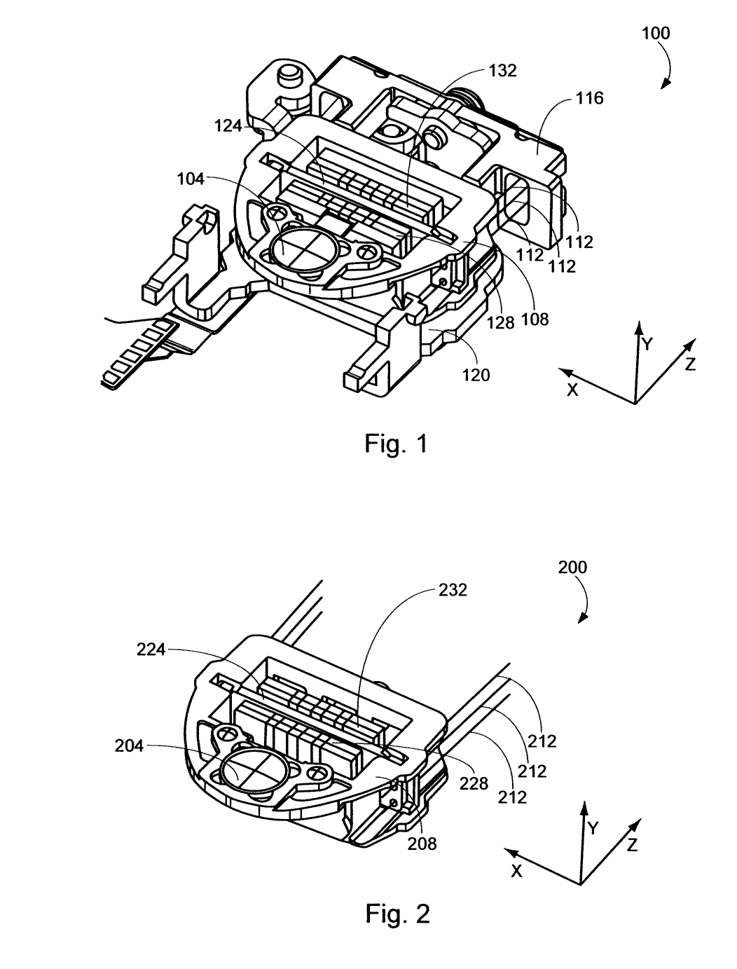

FIG. 1 is an overview of an electrical and/or optical device 100. The device 100 may be an optical recording and/or reproducing apparatus or system, a hard drive, electrical adjustment drive, electrical motor, electrical regulator, or other electrical and/or optical devices enabling a movable component. The movable component may comprise an optical pickup actuator that may move an optical lens over a storage medium, such as an optical disk.

The device 100 may include an objective lens 104, a lens holder 108, a support member 112, a holder 116, a base 120, a printed circuit board 124, and magnets 128 and 132. Fewer, more, or different components may form the device 100. In some devices, the objective lens 104 may be mounted on the lens holder 108, and an end of the support member 112 may be coupled with a side of the lens holder 108 and the other end of the support member 112 may be coupled with the holder 116, which may form part of the base 120. The lens holder 108 may move with respect to the base 120.

The printed circuit board 124 may be any device or component in which a circuit may be etched, printed, formed, burned, and/or applied on. The printed circuit board 124 may comprise a substrate that has many different shapes. The substrate may be rectangular, square, or triangular. Other geometrical shapes may be used too. The printed circuit board 124 may have a constant or varying thickness in one or more directions. The printed circuit board 124 may comprise a non-conductive material. Alternatively, the printed circuit board 124 may comprise conductive material or a composite of conductive and non-conductive material.

In some devices 100, the printed circuit board 124 may or may not be arranged between two (or more) magnets 128 and 132. The printed circuit board 124 may be coupled to the lens holder 108, and the magnets 128 and 132 may be coupled to or fixed to the base 120. In some devices 100, current flow through paths on or in the printed circuit board 124 may generate one or more magnetic fields that may interact with a constant or variable existing magnetic field, the constant or varying magnetic field may be produced by magnets 128 and 132. The interaction of the magnetic fields may force or allow the printed circuit board to move. The printed circuit board 124 may move along a substantially y-direction (focusing direction), x-direction (tracking direction), and/or tilt or rotate within an x-y plane. In some devices 100, the printed circuit board 124 may function as an actuator by moving the attached lens holder 108 and/or the objective lens 104 when the printed circuit board 124 moves. Alternatively, the magnets 128 and/or 132 may move in relation to the base 120 and may be attached to the lens holder 108 and/or the objective lens 104 instead of the printed circuit board 124. In such a device 100, the lens holder 108 and/or the objective lens 104 may move with the magnets 128 and/or 132.

FIG. 2 is a perspective view of a portion of a device 200. The device 200 may be an electrical and/or optical device. The device 200 may include an objective lens 204, a lens holder 208, a support member 212, a printed circuit board 224, and magnets 228 and 232. The device 200 may include components similar to or arranged like the components of device 100.

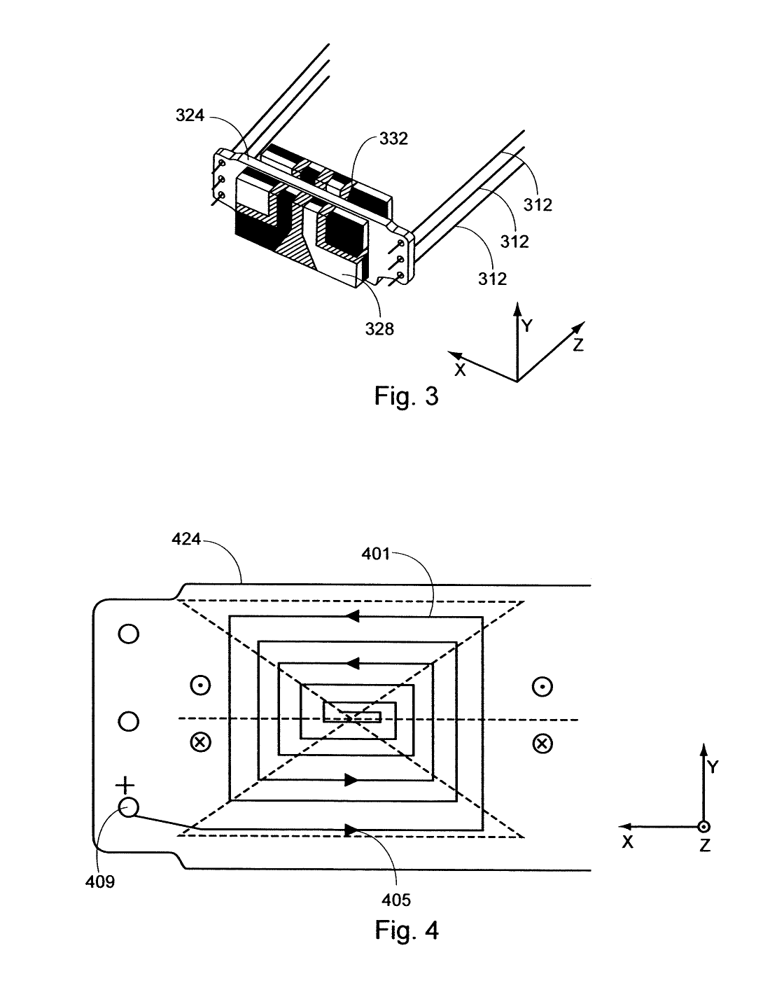

FIG. 3 is a perspective view of a printed circuit board 324. The printed circuit board 324 may be coupled with a support member 312 and may be arranged between magnets 328 and 332. The magnets 328 and 332 may be similar to the magnets 128, 228 and 132, 232, respectively. The magnets 328 and 332 may comprise 8-pole magnets, and each magnet may have a north pole portion, a south pole portion, and a neutral portion. The different portions may be arranged as any geometrical shape in any order. In FIG. 3, the portions shown in black may correspond to the north pole and the portions shown in white may correspond to the south pole (or vice versa). The neutral portions may comprise hatched regions. The magnet 328 and the magnet 332 may be arranged such that a pole, either north or south, of the magnet 328 may face the opposite pole of the magnet 332. Alternatively, more or less magnets and/or arrangements may be used. In some devices, magnets with fewer or more poles are used just as magnets with different polar and neutral portions (e.g., no neutral portions are used). In some devices one or more magnetic fields may be generated by other components or processes.

FIG. 4 is a schematic view of a portion of a printed circuit board 424, such as the printed circuit board 124, 224, and/or 324. A portion of the printed circuit board 424 may include a trace 401. The trace 401 may be a conductive path, a wire, or coil on top of, within, or beneath a surface of the printed circuit board 424. In some printed circuit boards 424, the trace 401 may be arranged in a winding or spiral fashion around a point of the printed circuit board 424. Portions of the trace may be associated with magnetically active and/or inactive domains.

Active domains may correspond to portions of trace 401 that facilitate current flow to create an electromagnetic force operable to move the printed circuit board 424. In some printed circuit boards 424, a current 405 may flow through trace 401 after passing through an input terminal 409. The terminal 409 may be near, on, or at an edge of the printed circuit board 424. Current 405 may flow counter-clockwise in a spiral or a winding pattern. The counter-clockwise pattern may provide the current 405 to flow in a negative x-direction for a lower part of the trace 401 arrangement and in a positive x-direction for an upper part of the trace 401 arrangement (or vice versa). The direction of the current 405 may be determined by Fleming's right hand rule.

Magnets 328 and 332 may generate a magnetic field that is perpendicular to the surface of the printed circuit board 424. Because the lines of magnetic flux pass from north to south, the upper part of the trace 401 arrangement may be within a magnetic field directed from a front side to a back side of the printed circuit board 424. Respectively, the lower part of the trace 401 arrangement may pass through a magnetic field directed from the back side to the front side of the printed circuit board 424. The force caused by the current 405 flow in both the upper and lower active domains may be directed in the negative y-direction. In FIG. 4, the active domains are framed areas that have a triangular shape. The active domains may correspond to different areas and may have different geometrical shapes.

The inactive domains that are outside of the framed areas may not contribute to the electromagnetic force. In the inactive domains, the current 405 may flow in the positive and negative y-directions. By this arrangement of the magnets 328 and 332 and the resulting magnetic flux, the forces generated by the inactive domains may cancel out.

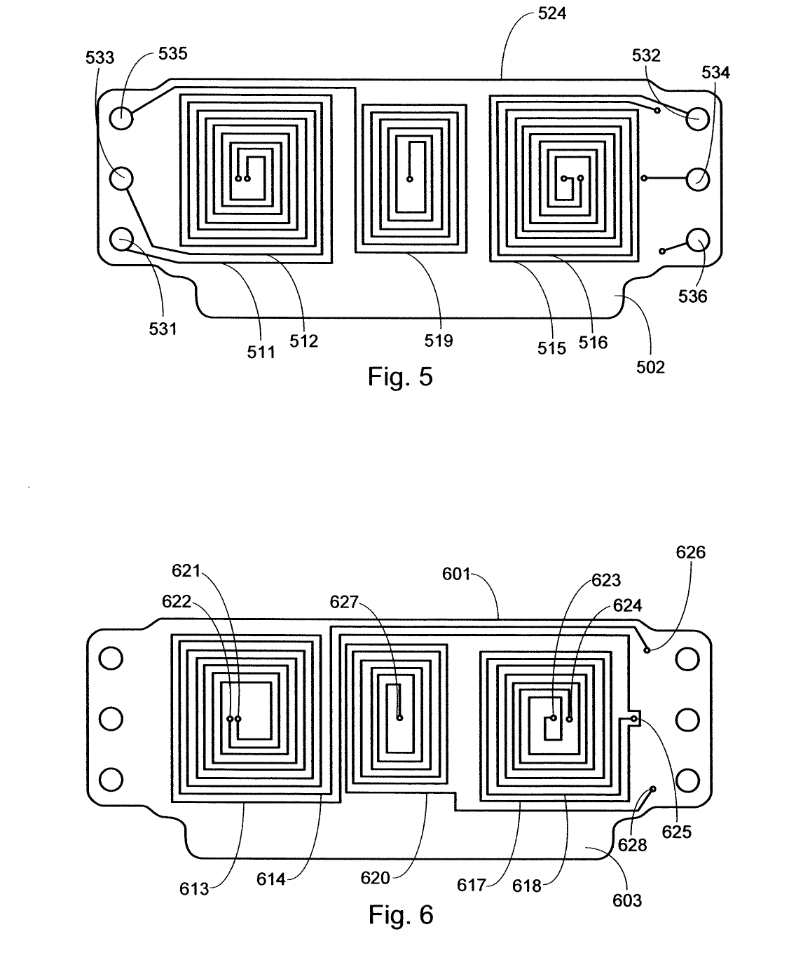

FIG. 5 is an overview of a first side of a printed circuit board 524, such as the printed circuit board 124, 224, 324, and/or 424. The printed circuit board 524 supports a surface 502. A pattern of conductive material may be printed, burned, formed, etched, or applied on, within, or beneath the surface 502. The pattern may include trace 511, trace 512, trace 519, trace 515, and trace 516. Each of the traces may similar to trace 401 and may be arranged in a winding or spiral shape. In some printed circuit boards 524, each trace may be wound clockwise around a substantially center point. Additionally, the traces 511 and 512 may be interleaved so that they are closely wound around a common point and alternate with respect to each other. Interleaving may form a relatively compact and space-saving circuit.

Similarly, the traces 515 and 516 may be alternatively wound around a common point, such that both traces 515 and 516 interleave with respect to each other. The traces 511, 512, 519, 515, and 516 may be arranged so that they do not overlap. The common or center points around which each trace may be respectively wound may be sufficiently spaced apart so that no trace touches another trace. The separation may inhibit, prevent, or minimize cross-currents. In some systems, fewer traces may be used. Different trace arrangements may be used. In some systems, two traces may be interleaved in a substantially clockwise direction and two other traces may be interleaved in a substantially counter-clockwise direction. Any combinations of interleaved trace arrangements may be used.

The printed circuit board may also include terminals 532, 534, 536, 531, 533, and 535. The terminals 531, 533, and 535 may be positioned near, on, or at an edge of the printed circuit board 524. The terminals 532, 534, and 536 may be positioned near, on, or at another edge of the printed circuit board. The terminals may be used to input and/or output current to and/or from the traces. In some printed circuit boards 524, the trace 511 is connected with the terminal 531. Trace 512 may be connected with the terminal 533, and trace 519 may be connected with the terminal 535. The trace 515 may be connected with the terminal 532. Alternatively, the terminals may be arranged on or at different portions of the printed circuit board 524.

FIG. 6 is an overview of a second side of a printed circuit board 601. The printed circuit board 601 may be similar or the same as the printed circuit board 524. The printed circuit board 601 may include a surface 603 that corresponds to an opposite surface, such as the surface 502. A pattern of conductive material may be printed, burned, formed, etched, or applied on, within or beneath the surface 603. The pattern includes a trace 613, a trace 614, a trace 620, a trace 617, and a trace 618. Each of the traces may be similar and may be arranged in a winding or spiral configuration. A winding direction about surface 603 may be in a substantially counterclockwise direction, when moving from the inside to the outside. The winding direction of the traces about surface 603 may be in an opposite direction about an opposite surface, such as the surface 502. The traces 613 and 614 may be interleaved with each other so that they are closely wound around a same centered point and alternate with respect to each other. The traces 617 and 618 may be interleaved like traces 613 and 614.

The interleaved traces may have substantially the same or different lengths. While maintaining a general direction of force, strength of the generated electromagnetic force may change with difference in trace length. It may be possible to reduce the length of some traces associated with a function, such as a tilt function, that may not need as much force as another function, such as a focus function.

The traces may be interconnected to form integrated or separate circuits. The circuits may be used for various functions, such as focus, tilt, and/or tracking function. In some printed circuit boards, a movement in a focus direction, such as a positive and negative y-direction, may occur through traces 511, 515, 613, and 617. The trace 511 may be connected with the trace 613 by a conducting interconnection or plated through-hole 621. The plated through-hole 621 may connect surfaces 502 and 603. The trace 613 may be connected with the trace 617 through a pathway or other connection on the surface 603. The pathway may comprise an extension of the trace 613 and/or 617. The trace 617 may be connected with the trace 615 through a connection 623 that may pass between the surfaces 502 and 603. The connection of the traces 511, 515, 613, and 617 may form a focus circuit. A current that may be received through the terminal 531 may flow through the interconnected traces to the terminal 532 to allow or force the printed circuit board to move in a positive or negative y-direction.

A tilt function, which may rotate the printed circuit board within the x-y-plane, may be facilitated through traces 512, 516, 614, and 618. The trace 512 may be connected with the trace 614 through a plated through-hole 622. The through-hole 622 may connect surfaces 502 and 603. The trace 614 may connect trace 516 through a pathway and through-hole 626. The pathway may be supported on a first and/or second surface of the printed circuit board. In some printed circuit boards, the pathway may be positioned on top of, within, or beneath the surface 603. The trace 516 may be connected with the trace 618 by a plated through-hole 624. The plated through-hole 624 may connect surfaces 502 and 603. The interconnection of the traces 512, 516, 614, and 618 may form a tilt circuit. A current received from terminal 533 may flow through the interconnected traces to the terminal 534 that may force the printed circuit board to move in a substantially x-y plane. A plated through-hole 625 may conduct current from the surface 603 to the surface 502.

A tracking function, which may move the printed circuit board in the positive or negative x-direction, may be provided by the traces 519 and 620. The trace 519 may be connected with trace 620 via a conductive path or plated through-hole 627. The through-hole 627 may be a via or any other connection allowing for a connection between the surfaces 502 and 603. The terminal 635 may be connected with the trace 519 via a pathway, and the trace 620 may be connected with the terminal 536 via different pathway and through-hole 628. The through-hole 628 may be a via or any other connection allowing for a connection between the surfaces 502 and 603, and the pathways may be extensions of the traces 519 and 620. The pathways may be either one and/or multiple surfaces of the printed circuit board. The interconnection of the traces 519 and 620 may form a tracking circuit. Current received from the terminal 635 may flow through the traces to the terminal 536. Current flow may allow the printed circuit board to move in a positive or negative direction substantially along the x-plane.

In different domains, current flow through the traces may change with changes in the magnetic flux. A magnetic force may be created in either a positive or a negative substantially y-direction. The tracking circuit may create an electromagnetic force in either the positive or negative substantially x-direction. To create a rotational force, the tilt-function may create opposing electromagnetic forces in a substantially y-direction on the left and right side of the printed circuit board. In some printed circuit boards, the traces 512 and 614 may be on a left side and create a force in the y-direction that is opposite the force created by the trace 516 and 618, which may be on a right side of the printed circuit board. Accordingly, the printed circuit board may be caused to rotate within the x-y-plane. Movement may occur substantially around an axis that may be perpendicular to the surfaces 502 and 603 and may pass through a point on the printed circuit board. The point may be substantially centered between the center point of the traces 511, 512, 613, and 614 and between the center point of the traces 515, 516, 617, and 618.

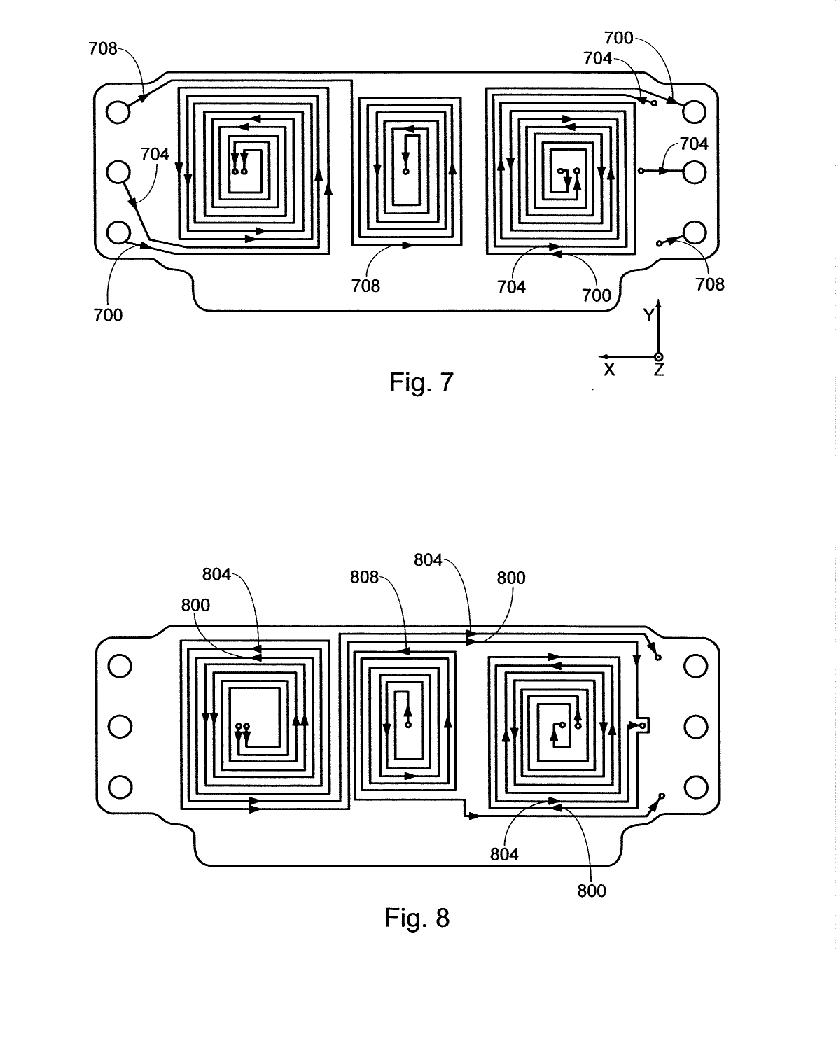

Based on the direction of input currents, the printed circuit board may be moved in two or more directions. FIG. 7 illustrates current flow on or in the surface 502, and FIG. 8 illustrates current flow on or in the surface 603. Current 700 may represent current of the focus circuit on or in the surface 502, and current 800 may represent current of the focus circuit on or in the surface 603. Current 704 may represent current of the tilt circuit on or in the surface 502, and current 804 may represent current of the tilt circuit on or in the surface 603. Current 708 may represent current of the tracking circuit on or in the surface 502, and current 808 may represent current of the tracking circuit on or in the surface 603.

The currents 700, 704, and 708 in the respective traces 511, 512, and 519 may flow in a counter-clockwise direction. Because of the interconnection of the traces 502 and 603, the direction of current 800, 804, and 808 flows may be predefined by the currents 700, 704, and 708 and/or vice versa. The direction of current flows may vary based on the positioning of the terminals and/or other features, such as through-holes, as well as the orientation to the winding of the traces.

For instance, the trace 613 and the trace 614, which may be connected with the trace 511 and the trace 512, respectively, may have currents 800 and 804 flowing in a counter-clockwise direction. This may occur because of the positioning of the conducting through-holes 621 and 622, which may be situated substantially in the middle of the traces 613 and 614. Also, the traces 613 and 614 may be wound in a counter-clockwise direction from the inside to the outside. Therefore, the currents 800 and 804 flow from the inside to the outside of the traces 613 and 614 in a counter-clockwise direction.

Current 808 may flow through trace 620 in a counter-clockwise direction, as the transition from one side of the printed circuit board to the other side may take place in the center of the two traces 619 and 620. The current 808 flows from the inner part to the outer part of the trace 620. Because of the trace arrangements, the current 800 may flow from the outside to the center of the trace 617 in a clockwise direction, and the current 700 may flow from the outside to the center of the trace 516 in a clockwise direction. However, the currents 804 and 704 may flow counterclockwise.

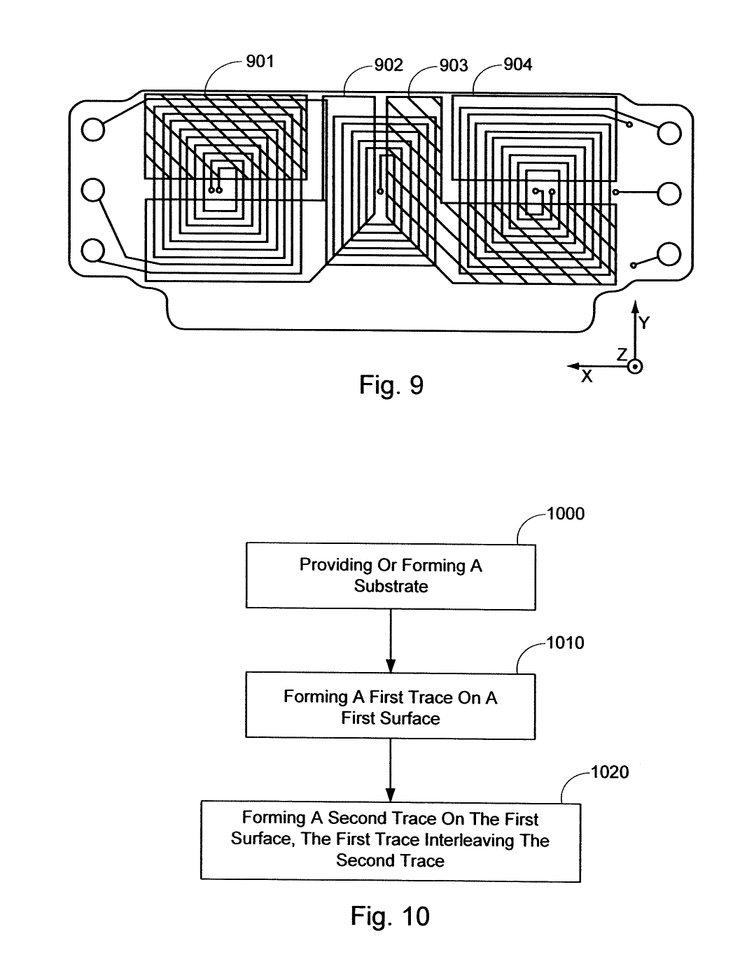

FIG. 9 illustrates magnetic field areas corresponding to the surface 502 of the printed circuit board. Areas 901, 902, 903, and 904 may correspond to portions of the printed circuit board in which a magnetic flux, such as a constant magnetic flux, may exist due to the magnets 328 and 332. The areas 901 and 904 may be substantially rectangular in shape, and the areas 902 and 903 may have substantially an L-shape. In other systems, the areas may have any other geometrical shape. The areas 901 and 902 may have a magnetic flux in one direction, and the areas 903 and 904 may have a magnetic flux in an opposite direction. In FIG. 9, hatched areas may denote one direction of magnetic flux and non-hatched areas may denote the opposite direction of magnetic flux, such as positive or negative z-directions. Alternatively, the areas may have any combination of directions of magnetic flux. The magnetic flux may also trespass the surface 603 in the same way as the surface 502.

The magnetic flux directions based on the magnets 328 and 332 may be combined with the magnetic flux created by the currents in the various traces of the surfaces 502 and 603. For illustration purposes, the areas 901 and 903 (or hatched areas) may represent magnetic flux in a positive substantially z-direction (from the back side to the front side of the printed circuit board), and the areas 902 and 904 (or non-hatched areas) may represent magnetic flux in a negative substantially z-direction (from the back side to the front side of the printed circuit board).

As a result, the upper area of the traces 511, 512, 613, and 614 and their respective currents 700, 704, 800, and 804, which may flow in a positive substantially x-direction, may be located within the area 901. The resulting electromagnetic forces may be directed in negative substantially y-direction. The currents that may be trespassed by the magnetic flux of the area 902, though they have an opposite direction than the currents in the area 901, may generate an electromagnetic force in the same negative substantially y-direction because the magnetic flux may also be opposite.

The magnetic flux of area 902 may also cause an electromagnetic force through the currents 708 and 808 of the traces 519 and 620. The generated electromagnetic force that may affect the printed circuit board may be directed in the positive substantially x-direction. This force may coincide with the electromagnetic force generated by the currents 708 and 808 flowing in the positive substantially y-direction and being within the magnetic field of area 903. Because the direction of the current and the magnetic flux in the area 903 may be opposite to the currents 708 and 808 in the area 902, the resulting forces may face in the same direction.

The traces 615 and 617 may have currents 700 and 800 flowing in a positive substantially x-direction in the area 903 and in a negative substantially x-direction in the area 904. Therefore, the resulting electromagnetic force may move the printed circuit board in a negative substantially y-direction. Furthermore, the currents 704 and 804 may flow in a counter-clockwise direction through the traces 516 and 618 and, therefore, in a negative substantially x-direction in the area 903 and in a positive substantially x-direction in the area 904. Current flow may generate a bias directed in a positive substantially y-direction. By changing the direction of the currents 700 and 800, the printed circuit board may be movable in substantially the y-direction.

Regarding the tilt function, the traces 512 and 614 may generate a force that is directed in negative substantially y-direction, and the traces 516 and 618 may generate a magnetic force in the positive substantially y-direction. Consequently, the printed circuit board may be rotated counter-clockwise within the substantially x-y-plane around an axis in z-direction. The axis may centered between the respective traces of the tilt circuit on the left and right side of the printed circuit board. Changing the direction of the current 704 and 804 may reverse the rotating direction to a clockwise rotation.

The tracking function may be implemented via the traces 519 and 620. The currents 708 and 808 may generate a force in a positive x-direction. By reversing the direction of the currents 708 and 808 the force may be directed to the negative x-direction.

Any of the features described above may be combined to perform methods of use or manufacture. In act 1000, a non-conductive substrate may be provided or formed. The substrate may support a printed circuit, to form a printed circuit board, such as the printed circuit board 124, 224, 324, 424, 524, and/or 601. The substrate may have a substantially rectangular, square, or triangular shape. The substrate may have a constant or varying thickness in one or more directions.

In act 1010, a first trace may be formed on or in a first surface of the substrate. The first trace may comprise trace 401, 511, 512, 515, 516, 613, 614, 617, and/or 618. The first trace may be a conductive path, a wire, or coil made supported on, within, or beneath the first surface, such as the surface 502. The first trace may be arranged in a winding or spiral fashion around a point of the substrate. The first trace may be printed, burned, formed, etched, or applied on, in or beneath the first surface of the substrate.

In act 1020, a second trace may be formed supported on or within the first surface of the substrate. The second trace may also be similar to the first trace. The first and second traces may interleave and may be configured to generate a first magnetic field through the current flow of currents 700, 704, 800, and 804. The first and second traces may be arranged around a first point, and the first magnetic field may interact with a second magnetic field, such as a magnetic field generated by the magnets 328 and 332, to move a movable component in a direction substantially coplanar to the first surface of the substrate. The moveable component may comprise an optical lens or lens holder of an optical pickup actuator.

In other acts, more traces may be interleaved on an opposite, second surface of the substrate. Any number of traces, through-holes, conductive paths, and/or terminals, as described above, may be formed or manufactured. A printed circuit board formed on the substrate may be placed or housed in an electrical and/or optical device or system, such as the device 100.

The interleaving of the traces may reduce a number of layers and may simplify the structure and/or production of a printed circuit board. However, the strength of the generated electromagnetic forces to move the printed circuit board in the focus, tracking, and/or tilt direction may remain the same. Also, the cost for constructing the printed circuit board may be decreased.

While various embodiments of the invention have been described, it will be apparent to those of ordinary skill in the art that many more embodiments and implementations are possible within the scope of the invention. Accordingly, the invention is not to be restricted except in light of the attached claims and their equivalents.

We claim:

1. A printed circuit board for use in an electrical or optical system, the printed circuit board comprising:
a substrate;
a first trace supported by the substrate having a first surface; and
a second trace supported by the substrate, the first trace interleaved with the second trace where current flow through the first trace and the second trace generate a first magnetic field, and
where the first trace and the second trace are positioned around a first point, and where the first magnetic field is operable to interact with a second magnetic field to move a movable component in a direction substantially coplanar to the first surface of the substrate.

2. The printed circuit board of claim 1, where the first trace and the second trace comprise spiral coils.

3. The printed circuit board of claim 1, where the first trace and the second trace have substantially the same length.

4. The printed circuit board of claim 1, where the first trace and the second trace have a different length.

5. The printed circuit board of claim 1, where the movable component comprises an objective lens of an optical pickup actuator.

6. The printed circuit board of claim 1, where the movable component comprises a lens holder of an optical pickup actuator.

7. The printed circuit board of claim 1, where the movable component is coupled to the substrate, and where the substrate is operable to move in the direction substantially coplanar to the first surface of the substrate when a first current and a second current flow respectively in the first trace and the second trace.

8. The printed circuit board of claim 1, further comprising:
a first terminal arranged near a first edge of the substrate;
a second terminal arranged near a second edge of the substrate, a first current operable to flow through the first trace from the first terminal to the second terminal;
a third terminal arranged near the first edge of the substrate; and
a fourth terminal arranged near the second edge of the substrate, a second current operable to flow through the second trace from the third terminal to the fourth terminal.

9. The printed circuit board of claim 1, further comprising:
a third trace supported by the substrate having a second surface opposite the first surface of the substrate, the third trace connected with the first trace by a first connection through the substrate; and
a fourth trace supported by the substrate, the fourth trace connected with the second trace by a second connection through the substrate, and
where the third trace and the fourth trace interleave around the first point.

10. The printed circuit board of claim 9, further comprising:
a fifth trace supported by the substrate; and
a sixth trace supported by the substrate, the fifth trace and the sixth trace interleave around a second point, and
where the first point and the second point are spaced apart and do not overlap with the fifth trace and the sixth trace.

11. The printed circuit board of claim 10, further comprising:
a seventh trace supported by the substrate, the seventh trace connected with the fifth trace by a third connection through the substrate; and
an eighth trace supported by the substrate, the eighth trace connected with the sixth trace by a fourth connection through the substrate, and
where the seventh trace and the eighth trace are arranged around the second point and are interleaved with respect to each other.

12. The printed circuit board of claim 11, where the eighth trace is connected with the fourth terminal by a fifth connection through the substrate.

13. The printed circuit board of claim 11, where the third trace is connected with the seventh trace by a first pathway on the second surface of the substrate, and where the fourth trace is connected with the sixth trace by a sixth connection through the substrate.

14. The printed circuit board of claim 11, where a third point lies on a first axis between the first point and the second point, and where a second axis passes through the third point and is substantially perpendicular to the first axis and within the plane of the first surface, and where the movable component is configured to move in a direction substantially parallel to the second axis when a first current flows through the first trace, the third trace, the fifth trace, and the seventh trace.

15. The printed circuit board of claim 14, where the movable component is operable to rotate around an axis substantially perpendicular to the first axis and the second axis when a second current flows through the second trace, the fourth trace, the sixth trace, and the eighth trace.

16. The printed circuit board of claim 14, further comprising:
a first terminal arranged near a first edge of the substrate; and
a second terminal arranged near a second edge of the substrate, a second current operable to flow through the ninth trace from the first terminal to the second terminal.

17. The printed circuit board of claim 14, further comprising:
a ninth trace supported by the substrate and an arranged around the third point, the third point spaced apart from the first point and the second point in which the ninth trace does not overlap the first trace, the second trace, the fifth trace, and the sixth trace, and
where the movable component is configured to move in a direction substantially parallel to the first axis when a second current flows in the ninth trace.

18. The printed circuit board of claim 17, further comprising:
a tenth trace supported by the substrate and arranged around the third point, the tenth trace connected with the ninth trace by a seventh connection through the substrate.

19. An electrical or optical actuator apparatus comprising:
a first magnet having a first pole;
a second magnet having a first pole and a second pole, the first pole of the first magnet positioned adjacent to the second pole of the second magnet;
a substrate having a first trace and a second trace interleaved with respect to each other and arranged around a first point, the substrate between the first magnet and the second magnet; and
a movable component configured to move when respective currents flow through the first trace and the second trace.

20. The electrical or optical actuator apparatus of claim 19, where the movable component is coupled with the substrate, and where the substrate is configured to move when the respective currents flow through the first and second traces.

21. The electrical or optical actuator apparatus of claim 19, where the movable component is coupled with at least one of the first magnet or second magnet, and where the first magnet or second magnet coupled with the movable component is configured to move when the respective currents flow through the first and second traces.

22. A method of manufacturing a printed circuit board for use in an electrical or optical system, the method comprising:
forming a first trace on a first surface;
forming a second trace on the first surface, the first trace interleaving the second trace,
where current flow through the first trace and the second trace generate a first magnetic field, and where the first trace and the second trace are arranged around a first point, and
where the first magnetic field is operable to interact with a second magnetic field to move a movable component in a direction substantially coplanar to the first surface of the substrate.
